(19) United States
(12) Patent Application Publication
(10) Pub. No.: US 2025/0275456 A1
(43) Pub. Date: Aug. 28, 2025

(54) DISPLAY BASEPLATE, MANUFACTURING METHOD FOR DISPLAY BASEPLATE, AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventor: Xuan Li, Beijing (CN)

(73) Assignees: Chengdu BOE Optoelectronics Technology Co., Ltd., Chengdu, Sichuan (CN); BOE TECHNOLOGY GROUP CO., LTD., Beijing (CN)

(21) Appl. No.: 18/859,810

(22) PCT Filed: Jan. 17, 2024
(86) PCT No.: PCT/CN2024/072799

§ 371 Date: Oct. 24, 2024

(30) Foreign Application Priority Data
Feb. 28, 2023 (CN) 202310193595.6

(51) Int. Cl. H10K 59/80; H10K 59/12

(52) U.S. Cl. CPC H10K 59/8793; H10K 59/1201; H10K 59/8792

(57) ABSTRACT

The present disclosure provides a display baseplate, a manufacturing method of a display baseplate and a display device, relating to the technical field of displaying. The display baseplate includes: a pore area, an active area located on at least one side of the pore area, and a transition area between the pore area and the active area; the display baseplate further includes: a light emitting baseplate, and a first structural layer located on a light emitting side of the light emitting baseplate; wherein a first structural layer located in the transition area and a first structural layer located in the active area have different structures, and have at least one identical material.

This application claims the priority of the Chinese patent application filed on Feb. 28, 2023, with the application number of 202310193595.6, and the title of “DISPLAY SUBSTRATE, MANUFACTURING METHOD FOR DISPLAY SUBSTRATE, AND DISPLAY DEVICE”, which is incorporated herein in its entirety by reference.

### TECHNICAL FIELD

The present disclosure relates to the technical field of displaying and more particularly, to a display baseplate, a manufacturing method of a display baseplate and a display device.

### BACKGROUND

With the development of display technology, active matrix organic light-emitting displays (hereinafter referred to as “OLED”), liquid crystal displays (hereinafter referred to as LCD), etc. have emerged. With the rise of micro display devices such as mobile phones, tablets, etc., it is generally necessary to form some openings on the display panel to place small devices (such as cameras).

### SUMMARY

The present disclosure provides a display baseplate, including: a pore area, an active area located on at least one side of the pore area, and a transition area between the pore area and the active area; wherein
the display baseplate further includes: a light emitting baseplate, and a first structural layer located on a light emitting side of the light emitting baseplate; wherein a first structural layer located in the transition area and a first structural layer located in the active area have different structures, and have at least one identical material.

Optionally, the first structural layer located in the transition area has a stripe.

Optionally, a fluctuation amplitude of a part of the stripe close to the pore area is greater than a fluctuation amplitude of a part of the stripe away from the pore area.

Optionally, the stripe includes at least one of a horizontal stripe, a wave-like stripe and a longitudinal stripe.

Optionally, the longitudinal stripe is close to the pore area, the wave-like stripe is distributed at one end of the longitudinal stripe away from the pore area, and the horizontal stripe is distributed at one end of the wave-like stripe away from the pore area.

Optionally, the stripe is distributed within a range of a distance that is greater than or equal to 2 nm, and less than or equal to 3 nm from a side wall of the pore area.

Optionally, the stripes are periodically arranged in a thickness direction of the first structural layer located in the transition area.

Optionally, a thickness of the first structural layer located in the transition area is different from a thickness of the first structural layer located in the active area.

Optionally, the thickness of the first structural layer located in the transition area is less than the thickness of the first structural layer located in the active area.

Optionally, a ratio of the thickness of the first structural layer located in the transition area to the thickness of the first structural layer located in the active area is less than or equal to 0.8.

Optionally, the first structural layer is configured for transmitting light in a target wavelength band, and converting incident linearly polarized light into circularly polarized light for transmission or reflection;
wherein the target wavelength band includes at least one wavelength band of a red light wavelength band, a blue light wavelength band and a green light wavelength band.

Optionally, the display baseplate further includes a second structural layer located on a side of the first structural layer away from the substrate; and the pore area exposes side walls of the first structural layer and the second structural layer, and exposed side wall are flush.

Optionally, the second structural layer is configured for reducing a reflectivity for light entering the display baseplate.

Optionally, the first structural layer is an organic composite thin film including a low melting point material.

Optionally, the transition area includes an isolated area and a peripheral area, the peripheral area is disposed close to the pore area, and the isolated area is disposed close to the active area;
the isolated area includes a substrate and at least one isolation column located above the substrate, the at least one isolation column surrounds a part or all of the peripheral area to surround the pore area;
wherein an orthographic projection of the first structural layer located in the transition area on the light emitting baseplate covers an orthographic projection of the at least one isolation column on the light emitting baseplate.

Optionally, the light emitting baseplate located in the active area includes:
a substrate;
a pixel circuit layer, disposed on a side of the substrate;
a flat layer, disposed on a side of the pixel circuit layer away from the substrate;
an organic luminescent layer, disposed on a side of the flat layer away from the substrate;
an encapsulation layer, disposed on a side of the organic luminescent layer away from the substrate; and
a light shielding layer, disposed on a side of the encapsulation layer away from the substrate, wherein an orthographic projection of the light shielding layer on the substrate is located in a non-pixel area of the organic luminescent layer;
wherein the first structural layer is located on a side of the light shielding layer away from the substrate.

Optionally, in a normal direction of the light emitting baseplate, the pore area completely penetrates the display baseplate or partially penetrates the display baseplate.

The present disclosure provides a manufacturing method of a display baseplate, and the method includes:
providing a light emitting baseplate;
forming a first structural layer on a light emitting side of the light emitting baseplate, to obtain an initial baseplate;
making openings on the initial baseplate, and forming a pore area, an active area, and a transition area between the pore area and the active area, to obtain the display baseplate; wherein a first structural layer located in the transition area and a first structural layer located in the active area have different structures, and have at least one identical material.

The present disclosure provides a display device, including the above display baseplate.

The display baseplate in the present disclosure is used, which includes: a pore area, an active area located on at least one side of the pore area, and a transition area between the pore area and the active area; wherein the display baseplate further includes: a light emitting baseplate, and a first structural layer located on a light emitting side of the light emitting baseplate; wherein a first structural layer located in the transition area and a first structural layer located in the active area have different structures, and have at least one identical material.

Since the used display baseplate includes the pore area and the transition area, the pore area can be used to place small devices, so that the display baseplate can be suitable for display devices that need to place small devices. In addition, due to the fact that the first structural layer in the transition area and the first structural layer located in the active area can have different structures, the first structural layer located in the transition area can better adapt to the pore area, that is, to meet the needs of opening holes, while the first structural layer located in the active area can better adapt to the active area, thereby ensuring the display quality of the active area. Among them, due to the fact that the first structural layer located in the transition area and the second structural layer located in the active area have at least one identical material, the first structural layer can be formed in one process, thereby improving production efficiency.

The above description is merely a summary of the technical solutions of the present disclosure. In order to more clearly know the technical means of the present disclosure to enable the implementation according to the contents of the description, and in order to make the above and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related art, the figures that are required to describe the embodiments or the related art will be briefly described below. Apparently, the figures that are described below are embodiments of the present disclosure, and a person skilled in the art can obtain other figures according to these figures without paying creative work.

FIG. 1 illustrates a top view of a display baseplate according to the present disclosure;

FIG. 2 illustrates a schematic diagram of a cross-section structure of the display baseplate shown in FIG. 1;

FIG. 3 illustrates a schematic diagram of a cross-section structure of an isolation column of a display baseplate;

FIG. 4a illustrates a schematic diagram of stripes in a first structural layer when overlooking a transition area;

FIG. 4b illustrates a schematic diagram of the stripes in the first structural layer when side-looking the transition area;

FIG. 5 illustrates a scanning electron microscope (SEM) image of a first structural layer of a transition area in a lateral view direction; and

FIG. 6 illustrates a flow chart of steps of a manufacturing method of a display baseplate according to the present disclosure.

### Description of Symbols

10—substrate, 101—active area, 102—transition area, 1021—isolated area, 1022—peripheral area, 103—pore area, 20—pixel circuit layer, 21—extension layer, 30—flat layer, 40—organic luminescent layer, 50—encapsulation layer, 601—light shielding layer, 602—optical bonding layer, 70—connection layer, 80—first structural layer, 90—second structural layer, 401—first electrode, 402—pixel definition layer, 403—organic material layer, 404—second electrode, x10—isolation column, x101—first barrier wall, x102—second barrier wall, x103—first isolation column, x104—second isolation column, x1031—first composite layer, x1032—first film layer, x1033—second film layer, x1041—second composite layer, x1042—passivation layer, x1043—boundary layer.

### DETAILED DESCRIPTION

In order to make the purpose, technical solution, and advantages of the embodiment of the present disclosure clearer, the technical solutions according to the embodiments of the present disclosure will be clearly and completely described below with reference to the drawings. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

With the application of a display panel in various electronic devices, it is necessary to design holes in the display panel to place small components, such as opening holes in the display screen of a mobile phone to place a front camera.

In view of this, the present disclosure provides a display baseplate, which may include a light emitting baseplate, a first structural layer is formed on the light emitting side of the light emitting baseplate. In order to achieve hole opening design without affecting the devices in the active area during opening holes, the light emitting baseplate may include an active area, a transition area, and a pore area. The first structural layer may include a structural layer located in the active area and a structural layer located in the transition area, so that the display baseplate can place small devices and form transition protection from the pore area to the active area through the first structural layer located in the transition area.

### Embodiment 1

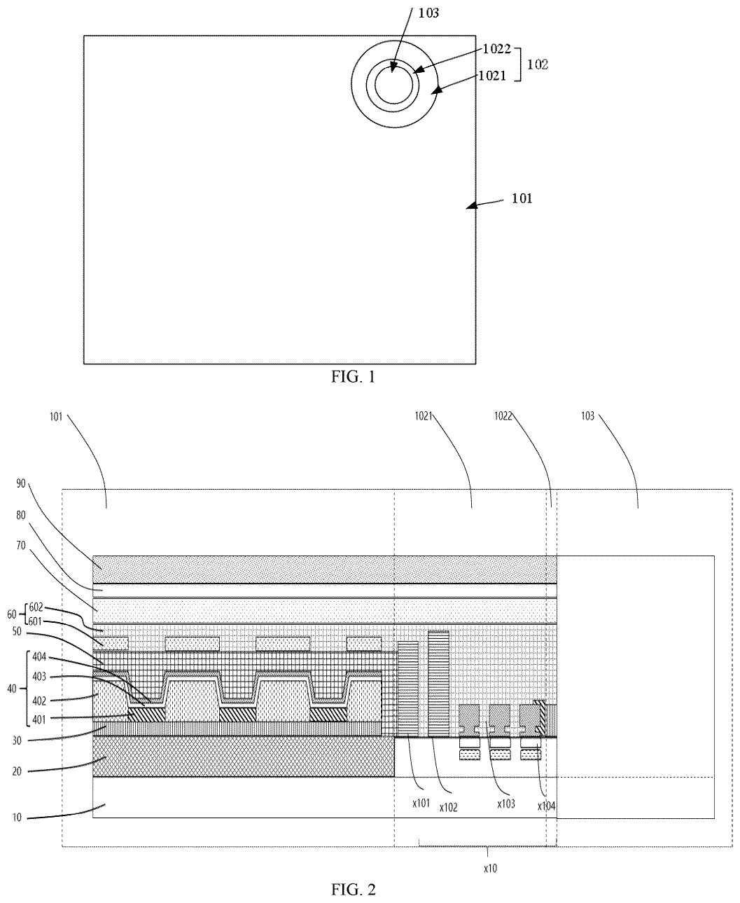

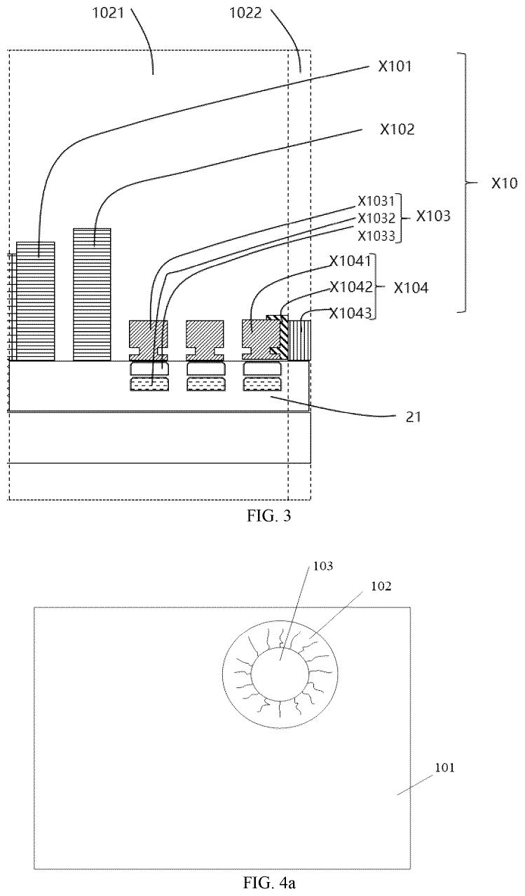

Referring to FIG. 1, FIG. 2, and FIG. 3, FIG. 1 illustrates a top view of a display baseplate in the present disclosure, FIG. 2 illustrates a schematic diagram of a cross-section structure of the display baseplate in the present disclosure, FIG. 3 illustrates a schematic diagram of a cross-section structure of an isolation column of the display baseplate in the present disclosure.

As shown in FIG. 1 and FIG. 2, the display baseplate in the present disclosure includes: a pore area 103, an active area 101 located on at least one side of the pore area 103, and a transition area 102 between the pore area 103 and the active area 101;
among them, the display baseplate further includes: a light emitting baseplate, and a first structural layer 80 located on a light emitting side of the light emitting baseplate; wherein a first structural layer 80 located in the transition area 102 and a first structural layer 80 located in the active area 101 have different structures, and have at least one identical material.

In this embodiment, the pore area 103 can refer to an area where holes have already been formed for placing small devices. The cross-sectional shape of the pore area 103 can be circular, square, rectangular, elliptical, etc., and is not limited here. From the pore area 103 outward, the transition area 102 and the active area 101 can be sequentially disposed. As shown in FIG. 1, the active area 101 surrounds the transition area 102, and the transition area 102 surrounds a part or all of the pore area 103. Specifically, the transition area 102 is formed on at least one side of the periphery of the pore area 103. That is to say, the transition area 102 can partially or completely surround the pore area 103. FIG. 1 shows the case where the transition area 102 surrounds all of the pore area 103, while in other cases, the transition area 102 can surround a part of the outer edge of the pore area 103. Next, the active area 101 surrounds a part or all of the transition area 102, as shown in FIG. 1. In the case where the transition area 102 surrounds all of the pore areas 103, the active area 101 surrounds all of the transition area 102. Certainly, in other embodiments, in the case where the transition area 102 surrounds all of the pore areas 103, the active area 101 may also surround a part of the transition area 102. Therefore, as a whole, the active area 101 is located on at least one side of the pore area 103, that is, the active area 101 surrounds a part or all of the pore area 103.

Among them, the light emitting baseplate can be an OLED baseplate. Specifically, the structure of the light emitting baseplate in the pore area 103, the structure of the light emitting baseplate in the active area 101, and the structure of the light emitting baseplate in the transition area 102 can be different. That is to say, the structures of the light emitting baseplate located in the pore area 103, the active area 101, and the transition area 102 can be partially different to fully adapt to the needs of the display baseplate for arranging the pore area 103.

Generally speaking, the light emitting baseplate in the active area 101 needs to have light-emitting devices that include the pixel units required by the display panel, while the light emitting baseplate in the transition area 102 may not have the light-emitting devices and instead have the structures required from the active area 101 to the pore area 103, such as the first structural layer 80 and the second structural layer 90 in the following embodiments. In some embodiments, the light emitting baseplate in the transition area 102 may also include an isolation column x10, which are located in the transition area 102 and can serve as a barrier wall between the pore area 103 and the active area 101 to protect the light-emitting devices in the active area 101. The light emitting baseplate in the pore area 103 may only include the substrate, or the light emitting baseplate located in the pore area 103 may be penetrated by the pore area 103, forming a hole.

For the light emitting baseplate, as shown in FIG. 3, the light emitting baseplate may include a substrate 20 and a light-emitting device layer located on one side of the substrate. The substrate 20 covers the entire active area 101, transition area 102, and pore area 103. The light-emitting device layer is located in the active area 101, that is, the projection of the light-emitting device layer on the substrate is located within the active area 101. Among them, the first structural layer 80 is located on the side of the light-emitting device layer away from the substrate, and the first structural layer 80 includes parts located in the transition area 102 and the active area 101. Among them, as shown in FIG. 3, the light-emitting device can be an OLED device, which has the advantages of a fast response speed, high luminous efficiency, high brightness, and a wide viewing angle. In some embodiments, the light-emitting device layer sequentially includes a pixel circuit layer 20, a flat layer 30, and an organic luminescent layer 40 from bottom to top. Among them, the organic luminescent layer 40 includes a series of functional layers, which can be referred to the structure of the OLED devices in related art.

The first structural layer 80 in this embodiment can be an organic structural layer, such as a composite film made of organic materials. Among them, the material of the first structural layer 80 located in the active area 101 and the material of the first structural layer 80 located in the transition area 102 can both be the same, so that they can be formed in one process. Alternatively, the material of the first structural layer 80 located in the active area 101 and the material of the first structural layer 80 located in the transition area 102 may be partially the same, so that the function achieved by the first structural layer 80 located in the active area 101 and the function achieved in the transition area 102 are partially different. For example, the material of the first structural layer 80 located in the active area 101 can achieve high transmittance transmission for the light emitted from the active area 101, while the material of the first structural layer 80 located in the transition area 102 can reduce damage to the active area 101 when forming the pore area 103.

Among them, according to the buffering transition requirements from the pore area 103 to the active area 101, the difference between the first structural layer 80 located in the transition area 102 and the first structural layer 80 located in the active area 101 can be: the thicknesses of the two are different, or the morphologies of the two are different, or both the thicknesses and morphologies of the two are different. Among them, the morphology can be understood as the appearance and microscopic morphology of the first structural layer 80, and the microscopic morphology can be observed through a microscope or magnifying glass. Specifically, in the case where the structure of the first structural layer 80 located in the transition area 102 is different from that of the first structural layer 80 located in the active area 101, the first structural layer 80 located in the transition area 102 can form protection for the active area 101 to avoid damage to the first structural layer 80 located in the active area 101 when opening holes to form the pore area 103 on the display baseplate, and avoid affecting the display quality of the active area 101.

The display baseplate used in the present disclosure has the pore area 103 and the transition area 102, so that the pore area 103 can be used to place the small devices, making the display baseplate suitable for the display devices that need to place the small devices. In addition, due to the fact that the first structural layer 80 located in the transition area 102 and the first structural layer 80 located in the active area 101 can have different structures, the first structural layer 80 located in the transition area 102 can better adapt to the pore area 103, that is, to meet the needs of opening holes, while the first structural layer 80 located in the active area 101 can better adapt to the active area 101, thereby ensuring the display quality of the active area 101. Among them, due to the fact that the first structural layer 80 located in the transition area 102 and the first structural layer 80 located in the active area 101 have at least one identical material, the first structural layer 80 can be formed in one process, thereby improving production efficiency.

In some embodiments, the pore area 103 completely or partially penetrates the display baseplate in the normal direction of the light emitting baseplate. Specifically, it can be determined whether to form a penetrated pore area 103 or a non-penetrated pore area 103 based on the small device to be placed in the pore area 103. Among them, the pore area 103 completely penetrates the display baseplate, which means that the pore area 103 penetrates the substrate layer of the light emitting baseplate, thereby allowing the pore area 103 to penetrate through the top and bottom. The pore area 103 partially penetrates the display baseplate, which means that the pore area 103 does not penetrate the substrate layer of the light emitting baseplate, so that the pore area 103 only opens on one side of the first structural layer 80, and forms a bottom of the pore area 103 on a side of the substrate. In this case, the small devices such as cameras can be placed.

For the material of the first structural layer 80, it can be a low melting point material, for example, the first structural layer 80 is an organic composite thin film including the low melting point material. In this case, the first structural layer 80 located in the transition area 102 and the first structural layer 80 located in the active area 101 can both be the same material, that is, the organic composite thin films made of the low melting point materials. Certainly, in some examples, the first structural layer 80 located in the transition area 102 and the first structural layer 80 located in the active area 101 can both include the organic composite thin films of the low melting point materials. The first structural layer 80 in the transition area 102 can also have other materials, or the first structural layer 80 in the active area 101 can also have other materials, such as materials that can enhance the transmittance of the light emitted by the light emitting baseplate.

Among them, for the structure of the first structural layer 80, the first structural layer 80 located in the transition area 102 and the first structural layer 80 located in the active area 101 may have different morphologies. In one example, the first structural layer 80 located in the transition area 102 has stripes, while the first structural layer 80 located in the active area 101 does not have stripes.

In some cases, the stripe can be distributed within the plane range of the first structural layer 80 in the transition area 102, that is, when viewed from the plane direction of the transition area 102, the stripe extending in the plane direction are formed in the transition area 102. The stripe can be multiple stripes distributed along the plane direction, or multiple stripes distributed at intervals along the normal direction of the transition area 102, that is, the thickness direction of the first structural layer 80.

Among them, the size of the transition area 102 in the plane direction may be larger than the extension size of the stripes in the plane direction.

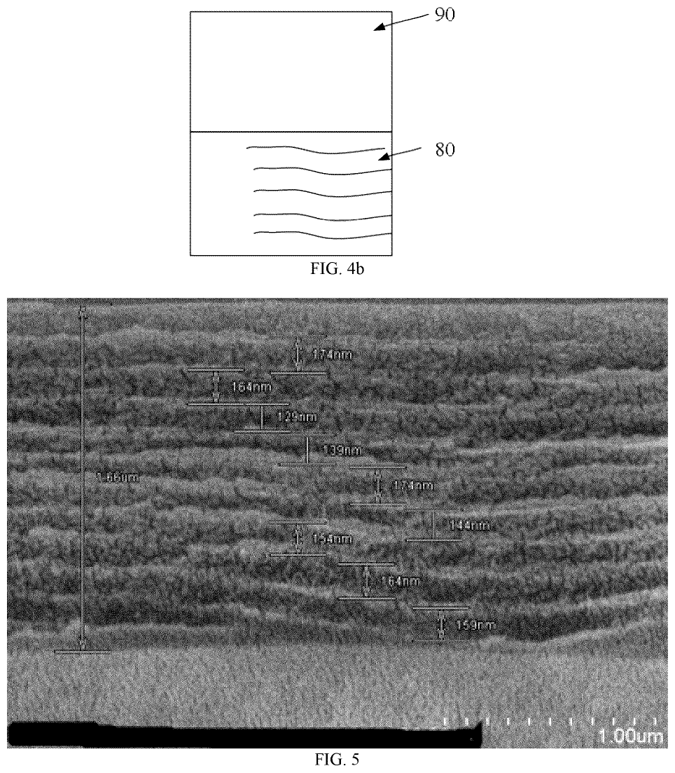

Referring to FIG. 4a, it illustrates a schematic diagram of stripes in the first structural layer 80 when overlooking the transition area 102. Referring to FIG. 4b, it illustrates a schematic diagram of the stripes in the first structural layer 80 when side-looking the transition area 102.

As shown in FIG. 4a, taking the circular pore area 103 as an example, the stripes extend in the plane direction of the first structural layer 80, and their extension direction can be a direction extending in a radiating manner from the pore area 103 to the edge of the transition area 102. There can be multiple stripes extending in the plane direction of the first structural layer 80, and the morphology of each stripe can be roughly the same, or there may be some stripes with significantly different shapes.

As shown in FIG. 4b, multiple stripes can be periodically distributed in the normal direction of the first structural layer 80, that is, in the thickness direction of the first structural layer 80. The morphology of each stripe can be roughly the same, or there may be some stripes with significantly different shapes. The spacing distance between the stripes can also be roughly the same.

Among them, the first structural layer 80 located in the transition area 102 can have more deformation space due to the presence of these stripes, thereby protecting the devices in the active area 101 from damage or interference caused by excessive device placement force when placing the small devices in the pore area 103.

In some examples, the stripes are distributed within a range of a distance that is greater than or equal to 2 nm, and less than or equal to 3 nm from a side wall of the pore area 103. For example, in the case where the pore area 103 is a circular pore area, in the transition area 102, the stripes can be distributed within the circular ring surrounding the pore area 103. In this case, it can also be considered that the extension length of the stripes in the plane direction of the first structural layer 80 is within the range of 2 nm˜3 nm.

In some another examples, the stripes are periodically arranged in the thickness direction of the first structural layer 80 located in the transition area 102. Referring to FIG. 5, it illustrates a scanning electron microscope (SEM) image of the first structural layer 80 of the transition area 102 in a lateral view direction. As shown in FIG. 5, there are multiple stripes distributed in the thickness direction of the first structural layer 80, and the distance between the stripes can be roughly the same. Therefore, it can be considered that they are periodically distributed in the thickness direction of the first structural layer 80.

There are several shapes of stripes to be illustrated below:
in some examples, based on the formation process of the pore area 103, the shape of the stripe can be that: a fluctuation amplitude of a part of the stripe close to the pore area 103 is greater than a fluctuation amplitude of a part of the stripe away from the pore area 103. As shown in FIG. 5, the left side of FIG. 5 is close to the pore area 103. It can be seen that the stripe near the pore area 103 has a larger fluctuation amplitude, while the stripe far away from the pore area 103 has a smaller fluctuation amplitude. The farther away from the pore area 103, the more horizontal stripes appear. In this case, the stripes can generally be formed in the opening process with the laser thermal cutting, because the closer to the pore area 103, the higher the temperature, so the fluctuation amplitude of the stripe formed is greater.

In some examples, the stripe include at least one of a horizontal stripe, a wave-like stripe and a longitudinal stripe. Among them, based on the formation process of the pore area 103, the stripe may also include only the horizontal stripe, or only the wave-like stripe, or only the longitudinal stripe. Alternatively, the stripe may include any two of the horizontal stripe, the wave-like stripe and the longitudinal stripe, or include all of the horizontal stripe, the wave-like stripe and the longitudinal stripe. As shown in FIG. 5, it includes the horizontal stripe, the wave-like stripe and the longitudinal stripe.

In some other examples, where the stripe include the horizontal stripe, the wave-like stripe and the longitudinal stripe, the longitudinal stripe is close to the pore area 103, the wave-like stripe is distributed at the end of the longitudinal stripe away from the pore area 103, and the horizontal stripe is distributed at the end of the wave-like stripe away from the pore area 103. That is to say, for a continuously extending stripe, it is horizontal in the section away from the pore area 103, forming a horizontal stripe, and it is longitudinal in the section close to the pore area 103, forming a longitudinal stripe, and the section between the horizontal stripe and the longitudinal stripe is the wave-like stripe.

Among them, for the structure of the first structural layer 80, in one example, the first structural layer 80 located in the transition area 102 and the first structural layer 80 located in the active area 101 have different thicknesses. When the thickness of the first structural layer 80 located in the transition area 102 is different from that of the first structural layer 80 located in the active area 101, it can fully adapt to the opening requirements of the transition area 102.

In some examples, the thickness of the first structural layer 80 located in the transition area 102 may be less than the thickness of the first structural layer 80 located in the active area 101. Certainly, in a more specific example, the ratio of the thickness of the first structural layer 80 located in the transition area 102 to the thickness of the first structural layer 80 located in the active area 101 is less than or equal to 0.8, preferably, the ratio may be 0.8.

Among them, when the thickness of the first structural layer 80 located in the transition area 102 is less than that of the first structural layer 80 located in the active area 101, it is possible to avoid significant deformation of the first structural layer during opening holes to form the pore area 103.

It will explain the function of the first structural layer 80 below:

In this embodiment, the first structural layer 80 can be an optical adjustment layer, which is used to increase the light output of the light emitting baseplate, such as improving the transmittance of light, thereby enhancing the luminous brightness of the display baseplate and reducing power consumption.

In some embodiments, the first structural layer 80 is configured for transmitting light in a target wavelength band, and converting incident linearly polarized light into circularly polarized light for transmission or reflection; wherein the target wavelength band includes at least one wavelength band of a red light wavelength band, a blue light wavelength band and a green light wavelength band.

Specifically, the first structural layer 80 can cover the red light wavelength band from 590 nm to 650 nm, the green light wavelength band from 500 nm to 570 nm, and the blue light wavelength band from 420 nm to 480 nm. For all of these wavelength bands, it has the function of converting the incident linearly polarized light into circularly polarized light for emission, and converting the incident circularly polarized light into linearly polarized light for reflection. For example, when the light emitted by the light emitting baseplate reaches the first structural layer 80, about 50% of the light in the wavelength band matching the target wavelength band passes through the first structural layer 80 due to different polarization states and is converted into the circularly polarized light; the remaining 50% of the light is reflected and also converted into the circularly polarized light. The transmitted circularly polarized light and the reflected circularly polarized light have opposite directions of circular polarization. Among them, the reflected circularly polarized light reaches the electrode layer in the light emitting baseplate, is reflected again, and converted into light with the same polarization direction as the circularly polarized light transmitted through the first structural layer 80, it may also achieve light emission through transmission, which can also achieve light gain effect, improve display brightness, and reduce the power consumption of the display device.

In some embodiments, as shown in FIG. 3, the display baseplate may further include an anti-reflection layer for preventing reflection for light entering the display baseplate, that is, it can be configured to reduce the reflectivity for light entering the display baseplate. In this way, it can prevent glare caused by external light reflecting off the display panel when it irradiates on the display panel, which could affect the user's viewing of the content on the display panel.

Specifically, the display baseplate further includes a second structural layer 90 located on a side of the first structural layer 80 away from the substrate; and the pore area 103 exposes side walls of the first structural layer 80 and the second structural layer 90, and exposed side wall are flush. Among them, the second structural layer 90 can be referred to as the anti-reflection layer, and in some examples, the second structural layer 90 can be implemented using a polarizer.

In some examples, the orthographic projection of the first structural layer 80 on the light emitting baseplate may coincide with the orthographic projection of the second structural layer 90 on the light emitting baseplate, or the orthographic projection of the first structural layer 80 on the light emitting baseplate may be covered by the orthographic projection of the second structural layer 90 on the light emitting baseplate. Alternatively, the orthographic projection of the first structural layer 80 on the light emitting baseplate can cover the orthographic projection of the second structural layer 90 on the light emitting baseplate.

Among them, the structure of the first structural layer 80 may be different from that of the second structural layer 90, and the structure of the second structural layer 90 located in the transition area 102 may also be different from that of the second structural layer 90 located in the active area 101.

Specifically, the thickness of the second structural layer 90 located in the transition area 102 may be different from that of the second structural layer 90 located in the active area 101. In this case, the thickness of the second structural layer 90 located in the transition area 102 may be greater than that of the second structural layer 90 located in the active area 101. In this way, protection can be provided to the active area 101 to prevent the formation of the pore area 103 and the damage of the devices placed in the pore area 103 to the active area 101.

Certainly, the morphology of the second structural layer 90 located in the transition area 102 can also be different from that of the second structural layer 90 located in the active area 101. In this case, the second structural layer 90 located in the transition area 102 has a melting and carbonization morphology, while the second structural layer 90 located in the active area 101 does not have the melting or carbonization morphology. This morphology characteristic can be formed during the formation process of the pore area 103.

Specifically, as shown in FIG. 5, in the transition area 102, the second structural layer 90 has a melted and carbonization morphology compared to the first structural layer 80. In this way, the second structural layer 90 can make the exposed film layer flatter, thereby facilitating the encapsulation of the encapsulation layer located above the second structural layer 90.

In some embodiments, to fully protect the active area 101 from the influence of the pore area 103, the transition area 102 can be divided into two areas, which together form two layers of protection from the pore area 103 to the active area 101, forming a gradient transition from the pore area 103 to the active area 101 to increase the protection effect on the active area 101.

Specifically, the transition area 102 may include an isolated area 1021 and a peripheral area 1022, the peripheral area 1022 is disposed close to the pore area 103, and the isolated area 1021 is disposed close to the active area 101. In this way, the peripheral area 1022 can form the first line of protection, while the isolation area 1021 can form the second line of protection. Among them, the peripheral area 1022 can be located on at least one side of the pore area 103, and the isolation area 1021 can surround the peripheral area 1022, that is to say, the peripheral area 1022 is located between the isolation area 1021 and the pore area 103. In some examples, the peripheral area 1022 may surround the pore area 103, and the isolation region 1021 may surround the peripheral area 1022.

Among them, a structure of the isolated area 1021 may include a substrate and an isolation column x10 located above the substrate, the isolation column x10 surrounds a part or all of the peripheral area 1022 to surround the pore area 103. Among them, an orthographic projection of the first structural layer 80 located in the transition area 102 on the light emitting baseplate covers an orthographic projection of the isolation column x10 on the light emitting baseplate.

As shown in FIG. 3, the isolation column x10 is located in the isolation area 1021, and multiple circles are spaced in the isolation area 1021 to surround the edge of the pore area 103 facing the active area 101. Specifically, multiple circles of isolation columns x10 can be formed, that is to say, multiple isolation columns x10 can form the multiple circles in the isolation area 1021. As shown in FIG. 3, there are multiple isolation columns x10 in the plane extension direction of the isolation area 1021, so that in the path from the pore area 103 to the active area 101, there are multiple isolation columns x10, so that multiple isolation columns x10 can be passed through.

Among them, the isolation column x10 close to the active area 101 can be used to isolate the organic luminescent materials inside the active area 101, forming a barrier wall to resist external water and oxygen, thereby improving the water and oxygen barrier performance of the display baseplate. The isolation column x10 close to the peripheral area 1022 can be used to form protection from the pore area 103 to the active area 101, in order to protect the devices inside the active area 101.

Among them, the thickness of the isolation column x10 close to the active area 101 may be greater than the thickness of the isolation column x10 close to the peripheral area 1022. As shown in FIG. 3, the distance from the surface, away from the substrate, of the isolation column x10 close to the active area 101 to the substrate is greater than the distance from the surface, away from the substrate, of the isolation column x10 close to the isolation area 1021 to the substrate.

For example, multiple circles of isolation columns x10 are formed from close to the active area 101 to close to the peripheral area 1022. For the two circles of isolation columns x10 (hereinafter referred to as barrier walls) close to the active area 101, the thickness of the first barrier wall closest to the active area 101 may be slightly less than that of the second barrier wall, while the remaining isolation columns x10 (hereinafter referred to as spacer columns) close to the peripheral area 1022, as shown in FIG. 3, it shows three circles of isolation columns x10, have the same thickness which is less than the thickness of the barrier wall close to the active area 101.

Among them, the structure of the barrier wall (the first barrier wall and the second barrier wall) and the structure of the spacer column may be different. In some examples, the spacer column may include a first isolation column x103 and a second isolation column x104, and the structures of the first isolation column x103 and the second isolation column x104 may be different. Among them, the spacer column closest to the peripheral area 1022 is the second isolation column x104, and the remaining spacer columns are the first isolation columns x103. Among them, the first isolation column x103 may include a first composite layer x1031

formed on one side of the substrate, a first film layer x1032 located on a side of the first composite layer away from the substrate, and a second film layer x1033 located on a side of the first film layer away from the substrate. The two film layers of the second isolation column x104 close to the substrate are made of the same material as the first composite layer and first film layer of the first isolation column x10 close to the substrate. The second isolation column x104 may include a second composite layer x1041 and a passivation layer x1042 located on a side of the second composite layer x1041 away from the substrate.

Among them, as shown in FIG. 3, a boundary layer x1043 is also disposed in the peripheral area 1022, and the boundary layer x1043 can be used together with the passivation layer x1042 as part of the second isolation column x104.

Among them, the materials of the first barrier wall and the second barrier wall can be the same as the material of the pixel definition layer 402 in the active area 101, so that they can be formed in one composition process.

Among them, the distance range between two adjacent isolation columns x10 in the plane extension direction of the substrate may be 8 μm to 10 μm. In an exemplary embodiment, the distance between the first isolation columns x10 and the second isolation columns x10 that are adjacent is 9.2 μm.

Among them, the embodiment of the present disclosure does not limit the number of isolation columns x10.

Among them, the first structural layer 80 is formed on the side of the isolation column x10 away from the substrate, and the orthographic projection of the first structural layer 80 on the substrate can cover the isolation columns x10 and the peripheral area 1022. In the case where the first structural layer 80 located in the transition area 102 has stripes, the stripes can cross the peripheral area 1022 to reach the isolation area 1021, or they can only be located in the peripheral area 1022. In the display baseplate, the structure of the peripheral area 1022 may include the substrate, the first structural layer 80, and the second structural layer 90.

Next, the light emitting baseplate in the embodiments of the present disclosure will be described. As mentioned above, the light emitting baseplate can be an OLED light-emitting baseplate, and the light-emitting device is an OLED device. As shown in FIG. 3, the light emitting baseplate located in the active area 101 includes: a substrate, a pixel circuit layer 20, a flat layer 30, an organic luminescent layer 40, an encapsulation layer 50, and a light shielding layer 601.

Among them, the pixel circuit layer 20 is disposed on a side of the substrate; the flat layer 30 is disposed on a side of the pixel circuit layer 20 away from the substrate; the organic luminescent layer 40 is disposed on a side of the flat layer 30 away from the substrate; the encapsulation layer 50 is disposed on a side of the organic luminescent layer 40 away from the substrate; and the light shielding layer 601 is disposed on a side of the encapsulation layer 50 away from the substrate, wherein an orthographic projection of the light shielding layer 601 on the substrate is located in a non-pixel area of the organic luminescent layer 40.

Among them, the first structural layer 80 is located on a side of the light shielding layer 601 away from the substrate, and covers the active area 101 and the transition area 102.

Among them, the substrate can be an integrated structure covering the active area 101 and the transition area 102, that is, the substrate includes a part located in the active area 101 and a part located in the transition area 102, and both parts are integrated structures. The encapsulation layer 50 can be located only in the active area 101, that is, the orthographic projection of the encapsulation layer 50 on the substrate covers the active area 101. Alternatively, the encapsulation layer 50 can also be located in the active area 101 and in a part of the transition area 102 adjacent to the active area 101, that is, the orthographic projection of the encapsulation layer 50 on the substrate covers the active area 101 and the part of the transition area 102. Certainly, the encapsulation layer 50 can also be located in the active area 101 and the transition area 102, that is, the orthographic projection of the encapsulation layer 50 on the substrate covers the active area 101 and the transition area 102.

Among them, the orthographic projection of the pixel circuit layer 20 on the substrate is located in the active area 101. In this case, an extension layer 21 of the pixel circuit layer 20 may be provided on a side of the substrate in the transition area 102, the material of the extension layer 21 is the same as part of the materials of the pixel circuit layer 20. The orthographic projection of the flat layer 30 on the substrate is also located in the active area 101. The pixel circuit layer 20 may include multiple data lines arranged in rows, multiple scanning lines arranged in columns, a driving transistor, and a scanning transistor. Among them, the intersection of the data lines and the scanning lines defines multiple pixel areas. The driving transistor controls the amount of the current provided to the organic luminescent layer 40 based on the voltage at the gate. The scanning transistor responds to the scanning signals of the scanning lines and provides a data voltage to the gate of the driving transistor. The data voltage is applied to the organic luminescent layer 40, thereby achieving the emission of light from the organic luminescent layer 40.

Among them, the orthographic projection of the organic luminescent layer 40 on the substrate is located in the active area 101. The organic luminescent layer 40 includes, from the side close to the substrate to the side away from the substrate, a first electrode 401, a pixel definition layer 402, an organic material layer 403, and a second electrode 404 in sequence. Among them, the pixel definition layer 402 includes an opening area and a non-opening area. The orthographic projection of the first electrode 401 on the substrate is located in the non-opening area, and the orthographic projection of the second electrode 404 on the substrate can cover the first electrode 401. The area where the opening area is located is the pixel area, and the area where the non-opening area is located is the non-pixel area. Among them, the first electrode 401 can be the anode, and the second electrode 404 can be the cathode.

The organic material layer 403 may include a hole injection layer HIL, a hole transport layer HTL, an emission layer EML, an electron transport layer ETL, and an electron injection layer EIL. Among them, when the voltage of the driving transistor in the pixel circuit layer 20 is applied to the anode and cathode, the holes passing through the HTL and the electrons passing through the ETL are transferred to the EML to form excitons, so that the emission layer EML can emit visible light.

Among them, the orthographic projection of the light shielding layer 601 on the substrate can cover the orthographic projection of the non-opening area on the substrate, that is, it can cover the orthographic projection of the non-pixel area on the substrate, or it can only coincide with the orthographic projection of the non-opening area on the substrate to achieve a higher pixel aperture ratio. In some embodiments, a connection layer 70 can also be provided between the light shielding layer 601 and the first structural layer 80. The orthographic projection of the connection layer 70 on the substrate can cover the active area 101, or can cover the active area 101 and the transition area 102. The connection layer 70 can also serve as the optical bonding layer 602.

In some examples, the light shielding layer 601 may be a black matrix.

In a specific embodiment, a display baseplate A is provided as follows:
as shown in FIG. 3, the display baseplate A includes: a pore area 103, a peripheral area 1022 surrounding the pore area 103, an isolation area 1021 surrounding the peripheral area 1022, and an active area 101 surrounding the isolation area 1021. Among them, the isolation region 1021 and the peripheral region 1022 form a transition area 102 between the pore area 103 and the active area 101.

In the active area 101, it includes a substrate, a pixel circuit layer 20, a flat layer 30, an organic luminescent layer 40, an encapsulation layer 50, a light shielding layer 601, a connection layer 70, a first structural layer 80, and a second structural layer 90.

Among them, the pixel circuit layer 20 is disposed on one side of the substrate, and includes multiple data lines arranged in rows, multiple scanning lines arranged in columns, driving transistors, and scanning transistors. Each group of the driving transistors and the scanning transistors is used to provide a data voltage to a pixel area in the organic luminescent layer 40.

Among them, the flat layer 30 is disposed on the side of the pixel circuit layer 20 away from the substrate, and the orthographic projection of the flat layer 30 on the substrate is also located in the active area 101.

Among them, the orthographic projection of the organic luminescent layer 40 on the substrate is located in the active area 101, which includes: a first electrode 401, a pixel definition layer 402, an organic material layer 403, and a second electrode 404. The first electrode 401 can be an anode, and the second electrode 404 can be a cathode.

Among them, the encapsulation layer 50 is disposed on the side of the organic luminescent layer 40 away from the substrate, and the orthographic projection of the encapsulation layer 50 on the substrate is located in the active area 101.

Among them, the light shielding layer 601 is disposed on the side of the encapsulation layer 50 away from the substrate, and the orthographic projection of the light shielding layer 601 on the substrate is located in the non-opening area defined by the pixel definition layer 402.

Among them, the connection layer 70 is disposed on the side of the light shielding layer 601 away from the substrate, and the orthographic projection of the connection layer 70 on the substrate covers the active area 101, the isolation area 1021, and the peripheral area 1022.

Among them, the first structural layer 80 is disposed on the side of the connection layer 70 away from the substrate, and the orthographic projection of the first structural layer 80 on the substrate covers the active area 101, the isolation area 1021, and the peripheral area 1022.

Among them, the second structural layer 90 is disposed on the side of the first structural layer 80 away from the substrate, and the orthographic projection of the second structural layer 90 on the substrate covers the active area 101, the isolation area 1021, and the peripheral area 1022.

Among them, the structure in the peripheral area 1022 includes a substrate, an extension layer 21 located on one side of the substrate, a first structural layer 80 and a second structural layer 90 that are located on one side of the extension layer 21.

Among them, the structure in the isolation area 1021 includes a substrate, an extension layer 21 located on one side of the substrate, multiple isolation columns x10 located on the side of the extension layer 21 away from the substrate, and a first structural layer 80 and a second structural layer 90 that are located on the side of the isolation columns x10 away from the substrate. Among them, the isolation columns x10 form multiple circles, with the two circles of isolation columns x10 (the aforementioned barrier wall) close to the active area 101 being higher, and the three circles of isolation columns x10 (the aforementioned isolation columns x10) close to the peripheral area 1022 being lower. For the two circles of isolation columns x10 close to the active area 101, a height of the isolation column x10 closest to the active area 101 is less than that of the isolation column x10 farther away from the active area 101.

Among them, the material of the extension layer is the same as a part of the materials of the pixel circuit layer 20.

Among them, the thickness of the first structural layer 80 located in the peripheral area 1022 and in a part of the isolated area 1021 is less than the thickness of the first structural layer 80 located in the active area 101. The material of the first structural layer 80 located in the peripheral area 1022 and in a part of the isolated area 1021 is the same as that of the first structural layer 80 located in the active area 101. The first structural layer 80 located in the peripheral area 1022 and in a part of the isolated area 1021 has the stripes, while the first structural layer 80 located in the active area 101 does not have the stripes, and the stripes transition from the horizontal stripe to the wave-like stripe and then to the longitudinal stripe from the active area 101 to the pore area 103.

### Embodiment 2

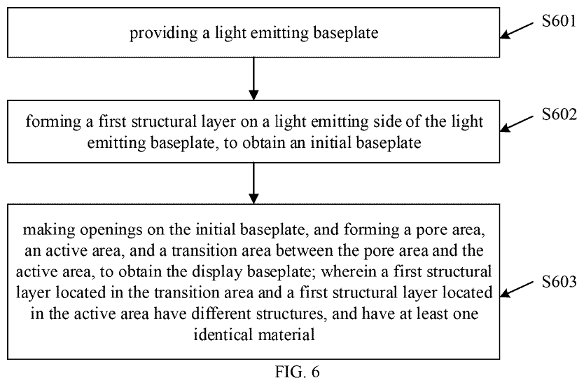

Based on the same inventive concept, the present disclosure also provides a manufacturing method of a display baseplate. Referring to FIG. 6, it illustrates a flow chart of the steps of the manufacturing method of the display baseplate, as shown in FIG. 6, which can specifically include the following steps:

Step S601: providing a light emitting baseplate;

Step S602: forming a first structural layer 80 on a light emitting side of the light emitting baseplate, to obtain an initial baseplate;

Step S603: making openings on the initial baseplate, and forming a pore area 103, an active area 101, and a transition area 102 between the pore area 103 and the active area 101, to obtain the display baseplate according to the above embodiment. Among them, a first structural layer 80 located in the transition area 102 and a first structural layer 80 located in the active area 101 have different structures, and have at least one identical material.

In this embodiment, when making openings on the initial baseplate to form the pore area 103, laser thermal cutting can be performed on the initial baseplate to form the pore area 103.

In some embodiments, taking the production of the above display baseplate A as an example, the structure of the provided light emitting baseplate may include: the substrate, the pixel definition layer 402, the light-emitting device, the encapsulation layer 50, the light shielding layer 601, and the connection layer 70.

Among them, the substrate can be divided into the active area 101, the transition area 102, and a hole-opening area. The hole-opening area is used to form the subsequent pore area 103. The active area 101 surrounds the transition area 102, and the transition area 102 surrounds the hole-opening area 1. Among them, the hole-opening is carried out in the hole-opening area.

Among them, the structure of active area 101 includes the substrate, the pixel circuit layer 20, the flat layer 30, the organic luminescent layer 40, the encapsulation layer 50, the light shielding layer 601, and the connection layer 70. Among them, the structures of the substrate, the pixel circuit layer 20, the flat layer 30, the organic luminescent layer 40, the encapsulation layer 50, the light shielding layer 601, and the connection layer 70 mentioned above can be seen in FIG. 3 and will not be repeated here.

Among them, the structure of the hole-opening area includes the substrate.

Among them, the first structural layer 80 is formed on the light emitting side of the light emitting baseplate, the orthographic projection of the first structural layer 80 on the substrate covers the active area 101, the transition area 102, and the hole-opening area. Additionally, the second structural layer 90 can be formed on the side of the first structural layer 80 away from the substrate, the orthographic projection of the second structural layer 90 on the substrate covers the active area 101, the transition area 102, and the hole-opening area.

The hole opening process is as follows:
the laser thermal cutting is performed in the hole-opening area to create holes. During the thermal cutting, the first structural layer 80 and the second structural layer 90 undergo deformation. The second structural layer 90 dissolves or carbonizes when heated during the hole opening process, so that the second structural layer 90 exhibits a dissolved or carbonized morphology on the side wall of the pore area 103. However, this does not affect the morphology of the remaining areas, and it remains a flat structural layer.

During the thermal cutting, the first structural layer 80 forms the stripes in the plane direction, the formed stripes are located in a circular range of 2-3 nm from the boundary of the pore area 103. However, the actual formed stripes may vary depending on factors such as cutting energy, a cutting speed, and a cutting direction. As shown in FIG. 5, it mainly includes the horizontal stripes, and the closer it is to the cutting heat source, the greater the change in the stripes, with more wave-like stripes and even diagonal downward longitudinal stripes appearing.

After cutting, the formed pore area 103 can expose the side walls of the first structural layer 80 and the second structural layer 90, and the exposed side walls are flush, that is, the exposed side walls of the first structural layer 80 and the second structural layer 90 are flush with each other, to facilitate to place the small devices.

By using the display device in the embodiment of the present disclosure, the small devices can be placed in the pore area. As the first structural layer located in the transition area and the first structural layer located in the active area can have different structures, the first structural layer located in the transition area can adapt to the needs of punching holes, while the first structural layer in the active area can better adapt to the active area, thereby ensuring the display quality of the active area.

Based on the same inventive concept, the present disclosure also provides a display device including the display baseplate as described above.

The various embodiments in this specification are described in a progressive manner, with each embodiment emphasizing its differences from other embodiments. The same and similar parts between the various embodiments can be referred to each other.

Finally, it should be noted that in this specification, relational terms such as first and second are only used to distinguish one entity or operation from another, and do not necessarily require or imply any actual relationship or order between these entities or operations. Moreover, the terms “including”, “comprising”, or any other variation thereof are intended to encompass non-exclusive inclusion, such that a process, method, good, or equipment that includes a series of elements includes not only those elements, but also other elements not explicitly listed, or elements inherent to such process, method, good, or equipment. Without further limitations, the element defined by the statement “including one . . . ” does not exclude the existence of other identical elements in the process, method, product, or device that includes the element in question.

The above provides a detailed introduction to a display baseplate, a manufacturing method of a display baseplate, and a display device provided in the present disclosure. Specific examples are applied in this specification to explain the principles and implementation methods of the present disclosure. The above embodiments are only used to help understand the method and core idea of the present disclosure. Meanwhile, for persons skilled in the art, there may be changes in the specific implementation methods and application scope based on the ideas disclosed in this specification. In summary, the content of this specification should not be understood as limiting the present disclosure.

After considering the specification and practicing the invention disclosed herein, persons skilled in the art will easily come up with other implementation solutions disclosed herein. The present disclosure is intended to cover any variations, uses, or adaptive changes of the present disclosure that follow the general principles of the present disclosure and include common knowledge or customary technical means in the art that are not disclosed in the present disclosure. The specification and embodiments are only considered exemplary, and the true scope and spirit of the present disclosure are indicated by the following claims.

It should be understood that the present disclosure is not limited to the precise structure described above and shown in the accompanying drawings, and various modifications and changes can be made without departing from its scope. The scope of the present disclosure is limited only by the appended claims.

The term “one embodiment”, “embodiment” or “one or more embodiments” referred to in this specification means that specific features, structures or characteristics described in conjunction with the embodiments are included in at least one embodiment disclosed herein. Furthermore, please note that the word “in one embodiment” may not necessarily refer to the same embodiment.

In the specification provided here, a large number of specific details are explained. However, it can be understood that the embodiments of the present disclosure can be practiced without these specific details. In some examples, well-known methods, structures, and techniques are not shown in detail to avoid blurring the understanding of this specification.

In the claims, any reference symbols located between parentheses should not be constructed as limitations on the claims. The word “comprising” does not exclude the existence of elements or steps that are not listed in the claims. The word “a/an” or “one” before the component does not exclude the existence of multiple such components. The present disclosure can be implemented by means of hardware comprising several different components and by means of appropriately programmed computers. In the unit claims listing several devices, several of these devices may be specifically embodied through the same hardware item. The use of words such as first, second, and third does not indicate any order. These words can be interpreted as names.

Finally, it should be noted that the above embodiments are only used to illustrate the technical solution of the present disclosure and not to limit it. Although the present disclosure has been described in detail with reference to the aforementioned embodiments, those skilled in the art should understand that they can still modify the technical solutions described in the aforementioned embodiments, or equivalently replace some of the technical features. And these modifications or substitutions do not depart from the essence and scope of the corresponding technical solutions disclosed in the present disclosure.

1. A display baseplate, comprising: a pore area, an active area located on at least one side of the pore area, and a transition area between the pore area and the active area; wherein
the display baseplate further comprises: a light emitting baseplate, and a first structural layer located on a light emitting side of the light emitting baseplate; wherein a first structural layer located in the transition area and a first structural layer located in the active area have different structures, and have at least one identical material.

2. The display baseplate according to claim 1, wherein the first structural layer located in the transition area has a stripe.

3. The display baseplate according to claim 2, wherein a fluctuation amplitude of a part of the stripe close to the pore area is greater than a fluctuation amplitude of a part of the stripe away from the pore area.

4. The display baseplate according to claim 2, wherein the stripe comprises at least one of a horizontal stripe, a wave-like stripe and a longitudinal stripe.

5. The display baseplate according to claim 4, wherein the longitudinal stripe is close to the pore area, the wave-like stripe is distributed at one end of the longitudinal stripe away from the pore area, and the horizontal stripe is distributed at one end of the wave-like stripe away from the pore area.

6. The display baseplate according to claim 2, wherein the stripe are distributed within a range of a distance that is greater than or equal to 2 nm, and less than or equal to 3 nm from a side wall of the pore area.

7. The display baseplate according to claim 2, wherein the stripes are periodically arranged in a thickness direction of the first structural layer located in the transition area.

8. The display baseplate according to claim 1, wherein a thickness of the first structural layer located in the transition area is different from a thickness of the first structural layer located in the active area.

9. The display baseplate according to claim 8, wherein the thickness of the first structural layer located in the transition area is less than the thickness of the first structural layer located in the active area.

10. The display baseplate according to claim 8, wherein a ratio of the thickness of the first structural layer located in the transition area to the thickness of the first structural layer located in the active area is less than or equal to 0.8.

11. The display baseplate according to claim 1, wherein the first structural layer is configured for transmitting light in a target wavelength band, and converting incident linearly polarized light into circularly polarized light for transmission or reflection;
wherein the target wavelength band comprises at least one wavelength band of a red light wavelength band, a blue light wavelength band and a green light wavelength band.

12. The display baseplate according to claim 1, wherein the display baseplate further comprises a second structural layer located on a side of the first structural layer away from the substrate; and the pore area exposes side walls of the first structural layer and the second structural layer, and exposed side wall are flush.

13. The display baseplate according to claim 12, wherein the second structural layer is configured for reducing a reflectivity for light entering the display baseplate.

14. The display baseplate according to claim 1, wherein the first structural layer is an organic composite thin film comprising a low melting point material.

15. The display baseplate according to claim 1, wherein the transition area comprises an isolated area and a peripheral area, the peripheral area is disposed close to the pore area, and the isolated area is disposed close to the active area;
the isolated area comprises a substrate and at least one isolation column located above the substrate, the at least one isolation column surrounds a part or all of the peripheral area to surround the pore area;
wherein an orthographic projection of the first structural layer located in the transition area on the light emitting baseplate covers an orthographic projection of the at least one isolation column on the light emitting baseplate.

16. The display baseplate according to claim 1, wherein the light emitting baseplate located in the active area comprises:
a substrate;
a pixel circuit layer, disposed on a side of the substrate;
a flat layer, disposed on a side of the pixel circuit layer away from the substrate;
an organic luminescent layer, disposed on a side of the flat layer away from the substrate;
an encapsulation layer, disposed on a side of the organic luminescent layer away from the substrate; and
a light shielding layer, disposed on a side of the encapsulation layer away from the substrate, wherein an orthographic projection of the light shielding layer on the substrate is located in a non-pixel area of the organic luminescent layer;
wherein the first structural layer is located on a side of the light shielding layer away from the substrate.

17. The display baseplate according to claim 1, wherein in a normal direction of the light emitting baseplate, the pore area completely penetrates the display baseplate or partially penetrates the display baseplate.

18. A manufacturing method of a display baseplate, wherein the method comprises:
providing a light emitting baseplate;
forming a first structural layer on a light emitting side of the light emitting baseplate, to obtain an initial baseplate;
making openings on the initial baseplate, and forming a pore area, an active area, and a transition area between the pore area and the active area, to obtain the display baseplate; wherein a first structural layer located in the transition area and a first structural layer located in the active area have different structures, and have at least one identical material.

19. A display device, comprising the display baseplate according to claim 1.
